(19) United States
(12) Patent Application Publication
(10) Pub. No.: US 2025/0258263 A1
(43) Pub. Date: Aug. 14, 2025

(54) Multiscale Magnetic Resonance Imaging with Motion Encoding Gradients Based on Basis Functions of an Integral Transform

(71) Applicant: Mayo Foundation for Medical Education and Research, Rochester, MN (US)

(72) Inventors: Yuan Le, Rochester, MN (US); Jun Chen, Rochester, MN (US); Richard L. Ehman, Rochester, MN (US)

(21) Appl. No.: 18/856,550

(22) PCT Filed: Apr. 12, 2023
(86) PCT No.: PCT/US2023/018310

§ 371 Date: Oct. 11, 2024

Related U.S. Application Data
(60) Provisional application No. 63/330,618, filed on Apr. 13, 2022.

(51) Int. Cl. G01R 33/563; G01R 33/56

(52) U.S. Cl. CPC G01R 33/56358; G01R 33/5608

(57) ABSTRACT

Described here are systems and methods for magnetic resonance imaging using motion encoding gradients that are shaped based on one or more basis functions of an integral transform. These motion encoding gradients are capable of encoding broadband tissue motion. The motion encoding gradients can implement multiple scales, shapes, or variations of one or more basis functions, series, or systems to facilitate encoding and detecting broadband tissue motion. The underlying tissue motion can be decoded using an inverse transform corresponding to the inverse of the integral transform on which the one or more basis functions are based.

### CROSS-REFERENCE TO RELATED APPLICATIONS

This application claims the benefit of U.S. Provisional Patent Application Ser. No. 63/330,618, filed on Apr. 13, 2022, and entitled “Multiscale Magnetic Resonance Imaging with Motion Encoding Gradients Based on Basis Functions of an Integral Transform,” which is herein incorporated by reference in its entirety.

### STATEMENT OF FEDERALLY SPONSORED RESEARCH

This invention was made with government support under EB001981 awarded by the National Institutes of Health. The government has certain rights in the invention.

### BACKGROUND

Phase contrast magnetic resonance imaging (“PC-MRI”) is a group of MRI techniques that detect tissue motion, such as blood flow for flow imaging or tissue shear wave motion in magnetic resonance elastography (“MRE”). In MRE, motion encoding gradients (“MEGs”) are used to encode tissue motion into the phase images obtained with MRI. The MEGs are traditionally shaped as bipolar trapezoidal waves or sinusoidal waves, either with one or multiple cycles. By acquiring the same image twice with positive and negative MEG encoding (e.g., alternating the polarity of the MEGs from one repetition to the next), the phase contrast images are calculated as the difference in the image phase. By repeating this process multiple times with different time delays between the underlying motion and the MEGs, tissue motion can be derived and a time series of images depicting the moving tissue can be obtained.

Currently the shapes of the MEG waveforms are the same for all timepoints. In that case, especially in MRE, when the tissue motion becomes complicated (e.g., in multi-frequency MRE and transient MRE), the MEGs need to be carefully selected in order to depict a broad-band motion faithfully, and the reconstruction techniques becomes complex and time consuming.

### SUMMARY OF THE DISCLOSURE

The present disclosure addresses the aforementioned drawbacks by providing A method for magnetic resonance elastography. The method includes acquiring magnetic resonance elastography (“MRE”) data from a subject using a magnetic resonance imaging (“MRI”) system performing a pulse sequence that includes motion encoding gradients that are shaped based on a wavelet basis function. The MRE data are acquired while mechanical waves are propagating in at least one tissue of the subject. Images are reconstructed from the MRE data, and motion data are generated from the images by applying an inverse wavelet transform to the images, where the inverse wavelet transform corresponds to the wavelet basis function used to shape the motion encoding gradients. Mechanical property value data are estimated from the motion data, where the mechanical property value data are indicative of a mechanical property of the at least one tissue in the subject.

It is another aspect of the present disclosure to provide an MRI system that includes a main magnet configured to generate a polarizing magnetic field, a gradient system including at least one gradient coil configured to generate a magnetic field gradient, a radio frequency (“RF”) system including at least one RF coil, and a computer system in communication with the gradient system and the RF system. The computer system is configured to access a motion encoding gradient waveform that is shaped based on a wavelet basis function, and to control the gradient system to generate a magnetic field gradient in response to the motion encoding gradient waveform.

The foregoing and other aspects and advantages of the present disclosure will appear from the following description. In the description, reference is made to the accompanying drawings that form a part hereof, and in which there is shown by way of illustration one or more embodiments. These embodiments do not necessarily represent the full scope of the invention, however, and reference is therefore made to the claims and herein for interpreting the scope of the invention.

### BRIEF DESCRIPTION OF THE DRAWINGS

FIG. 1A is an example pulse sequence diagram illustrating a multiscale phase-contrast pulse sequence (e.g., a magnetic resonance elastography pulse sequence) based on a spin-echo echo planar imaging pulse sequence and using multiscale motion encoding gradients shaped based on different scales of a Haar wavelet basis function.

FIG. 1B is an example pulse sequence diagram illustrating a multiscale phase-contrast pulse sequence (e.g., a magnetic resonance elastography pulse sequence) based on a spin-echo echo planar imaging pulse sequence and using multiscale motion encoding gradients shaped based on basis functions associated with different harmonics of a Fourier series.

FIG. 2 is a flowchart setting forth the steps of an example method for magnetic resonance elastography using the systems and methods described in the present disclosure.

FIGS. 3A-3D illustrate example motion encoding gradient waveforms based on different scales of a Haar wavelet basis function (FIG. 3A-3C) and a corresponding process for decoding the underlying motion profile based on an inverse Haar wavelet transform.

FIGS. 4A and 4B illustrate example motion encoding gradient waveforms based on different harmonics of a Fourier series (FIG. 4A) and a corresponding process for decoding the underlying motion profile based on an inverse Fourier transform (FIG. 4B).

FIG. 5 is a block diagram of an example magnetic resonance imaging (“MRI”) system that can implement the systems and methods described in the present disclosure.

### DETAILED DESCRIPTION

Described here are systems and methods for designing and using motion encoding gradients that are shaped based on basis functions of an integral transform in order to improve the detection of coherent tissue motion with multiple frequencies. When used in MRE, an external vibration source generates mechanical waves in a tissue, and these mechanical waves are measured and used to characterize that tissue. In particular, the mechanical waves alter the phase of the measurable magnetic resonance signals, and from this phase information the mechanical properties (e.g., Young's modulus, Poisson's ratio, shear modulus, bulk modulus, and so on) of the tissue can be determined. The systems and methods described in the present disclosure implement motion encoding gradient pulses of multiple scales (i.e., multi-scale MRE) in order to encode and detect broadband tissue motion, such as motion corresponding to mechanical waves of multiple frequencies.

As an example, motion encoding gradient pulses can be designed and timed to approximate a finite number of the basis functions of an integral transform. As one non-limiting example, the MEGs can be designed to approximate the basis functions corresponding to a finite number of scales (e.g., 2-3 scales) in a Haar wavelet system. For instance, by using multiple motion encoding gradients of this type, and by slightly modifying the shape of different ones of the motion encoding gradients, a Haar wavelet series can be approximated. In this example, an inverse Haar transform can then be used to decode the tissue displacement. When these MEGs are implemented for MRE, the following data processing used to produce elastogram images (e.g., mechanical property maps) can be significantly simplified, and the contrast and signal-to-noise ratio can be improved relative to more conventional MRE techniques. As another non-limiting example, the MEGs can be designed to approximate other basis functions of an integral transform. For example, the MEGs can be designed to approximate the basis functions corresponding to a finite number of harmonics of a Fourier series, or the like.

In phase-contrast MRI techniques (e.g., MRE, phase-contrast flow imaging), the accumulated phase due to motion for each voxel is given by,

$$θ ( t ) = \frac{γ}{2 π} {\int }_{0}^{t} \vec{G ( τ )} \cdot \vec{r ( τ )} d τ ;$$

where G(τ) is the motion encoding gradient and r(τ) is the displacement caused by the tissue motion. The accumulated phase can be interpreted as a projection of the motion to the motion encoding gradient. By designing the motion encoding gradients based on the group of basis functions, the phase can approximate a corresponding integral transform of the motion. For example, by designing the motion encoding gradients as a Haar wavelet series, the phase will approximate the Haar transform of the motion. Likewise, by designing the motion encoding gradients as a Fourier series, the phase will approximate the Fourier transform. As a result, the displacement can be decoded using the corresponding inverse transform (e.g., the inverse Haar transform, the inverse Fourier transform).

As an example, the motion encoding gradients can be designed in the shape of a Haar wavelet series based on the following equations:

$$Scaling function : φ ( t ) = \{ \begin{matrix}1 & 0 \leq t < 1 \\ 0 & otherwise\end{matrix}$$

$$mother wavelet function : φ ( t ) = \{ \begin{matrix}1 & 0 \leq t < 1 / 2 \\ - 1 & \frac{1}{2} \leq t < 1 \\ 0 & otherwise\end{matrix}$$

$$wavelet function : {φ}_{j , k} ( t ) = \{ \begin{matrix}{\sqrt{2}}^{j} & \frac{k - 1}{{2}^{j}} \leq t < \frac{k - 1 / 2}{{2}^{j}} \\ - {\sqrt{2}}^{j} & \frac{k - 1 / 2}{{2}^{j}} \leq t < \frac{k}{{2}^{j}} \\ 0 & otherwise\end{matrix} ;$$

where j and k are integer values. In this example, the phase will approximate the Haar transform of the motion as,

$${a}_{0} = \frac{1}{{2}^{n}} {\int }_{0}^{1} f ( t ) φ ( t ) dt$$

$${a}_{1} = \frac{1}{{2}^{n}} {\int }_{0}^{1} f ( t ) ψ ( t ) dt$$

$${a}_{j , k} = \frac{1}{{2}^{n}} {\int }_{0}^{1} f ( t ) {ψ}_{j , k} ( t ) dt ;$$

where n is an integer value. Then, as stated above, displacement can be decoded using the inverse Haar transform as,

$${f}_{n} ( t ) = {a}_{0} φ ( t ) + {a}_{1} ψ ( t ) + {\sum }_{\begin{matrix}2 \leq j \leq n \\ 0 \leq k < {2}^{j - 1}\end{matrix}} {a}_{j , k} {φ}_{j , k} ( t ) .$$

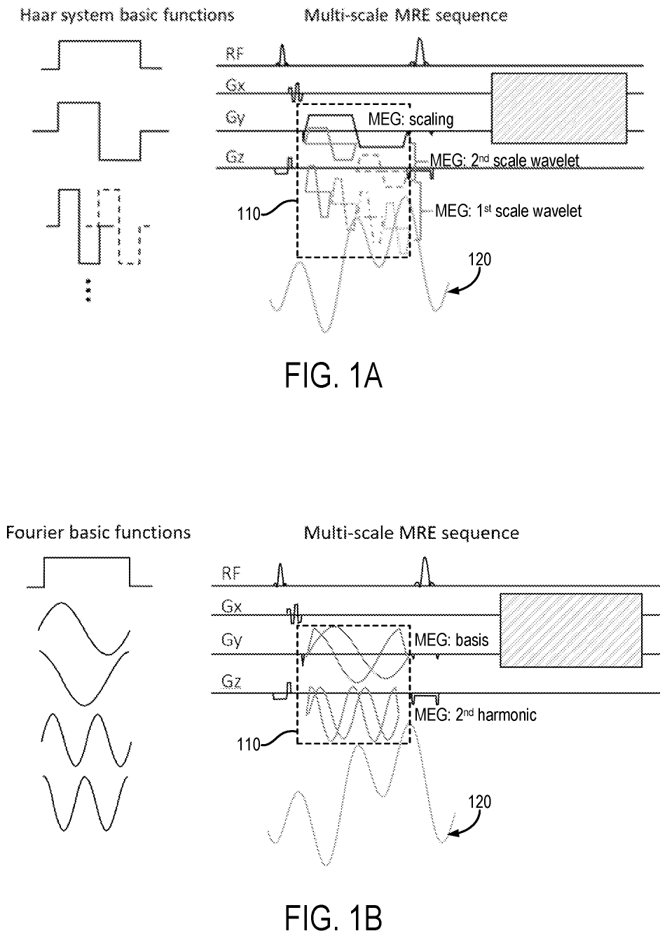

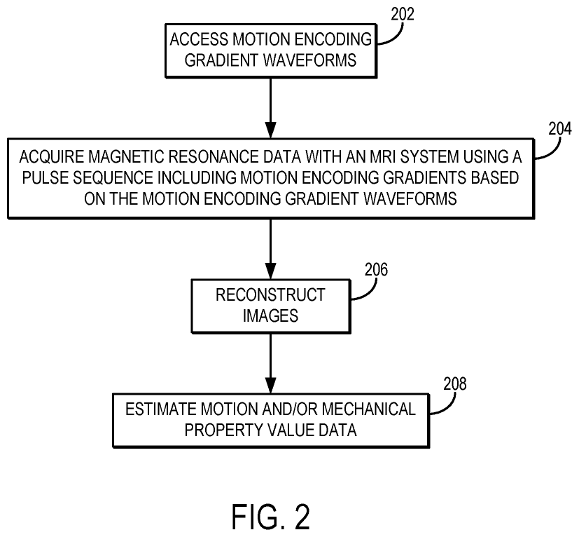

An example pulse sequence implementing motion encoding gradients that are shaped based on a wavelet basis function is illustrated in FIG. 1A. In this example, the pulse sequence is based on a spin-echo based echo planar imaging (“EPI”) MRE pulse sequence, in which the motion encoding gradients are shaped based on a Haar wavelet series. In other examples, the motion encoding gradients can be shaped based on wavelet basis functions, series, or systems other than the Haar wavelet series. Likewise, although a spin echo EPI pulse sequence is illustrated, other types of pulse sequences can also be implemented, including gradient echo EPI pulse sequences, and pulse sequences that utilize a data acquisition scheme other than EPI.

In some embodiments, the motion encoding gradients include a set gradients that are scaled by different wavelet basis functions. In these examples, a basis function is selected as a base function (or mother function). The base function is scaled using different scaling factors or functions to create scaled basis functions. For instance, as shown in FIG. 1A, the motion encoding gradients 110 are shaped using different scales of wavelet basis function; thus, the pulse sequence may be referred to as a multiscale MRE pulse sequence. Using multiple different wavelet scales for shaping the motion encoding gradients 110 allows for more robust encoding of multifrequency motions, such as the multifrequency motion profile 120 illustrated in FIG. 1A. As another example, the motion encoding gradients 110 can be shaped based on other basis functions, as described above. For instance, as illustrated in FIG. 1B, the motion encoding gradients 110 could instead be shaped based on different harmonics of a Fourier series. More generally, the motion encoding gradients 110 can be shaped based on a finite number of the basis functions of an integral transform.

Although the pulse sequences illustrated in FIGS. 1A and 1B are described with respect to MRE applications, it will be appreciated by those skilled in the art that the motion encoding gradients 110 can be implemented in pulse sequences for other imaging applications, such as to detect coherent tissue motion using techniques other than MRE. As a non-limiting example, in some instances, the motion encoding gradients 110 can be implemented in a pulse sequence for phase-contrast flow imaging.

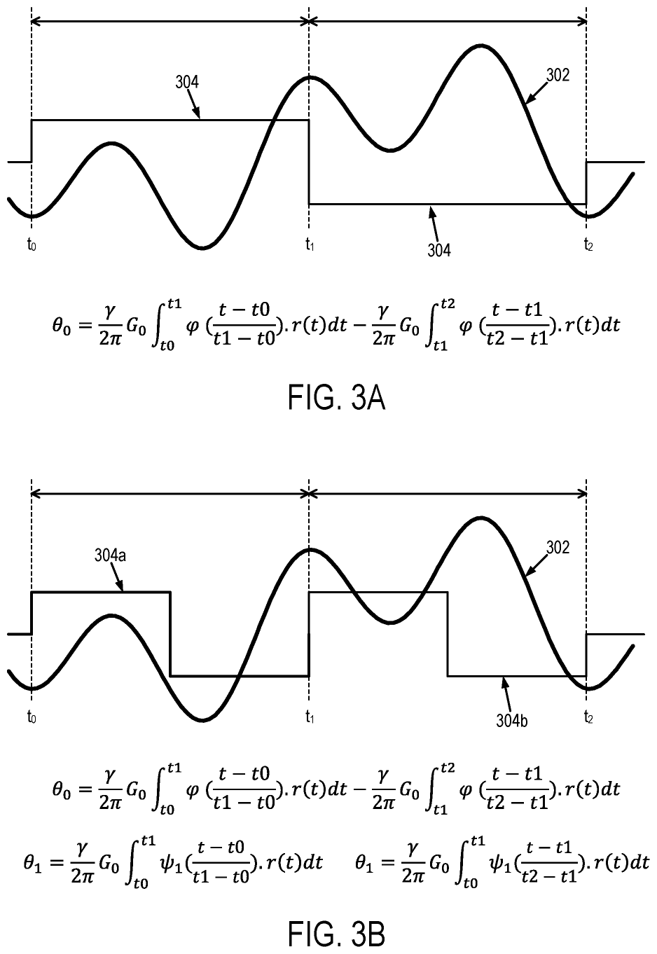

Referring now to FIG. 2, a flowchart is illustrated as setting forth the steps of an example method for magnetic resonance elastography using motion encoding gradients that are scaled or otherwise based on basis functions, series, or systems corresponding to a particular integral transform, such as the Haar wavelet system (or other wavelet systems), the Fourier series, or the like.

The method includes accessing motion encoding gradient (“MEG”) waveforms with a computer system, as indicated at step 202. In general, the MEG waveforms define the shape of motion encoding gradients that are generated by the gradient coils of an MRI system in response to the MEG waveforms. The MEG waveforms can be accessed by the computer system by retrieving previously constructed MEG waveforms from a memory or other data storage or medium. Additionally or alternatively, the MEG waveforms can be accessed by constructing them with the computer system, such as in response to a user input. The computer system can be a part of the MRI system, such as an operator workstation, a pulse sequence server, or the like.

As described above, the MEG waveforms are constructed to be shaped based on one or more basis functions, series, or systems. As a non-limiting example, the MEG waveforms include gradient waveforms that are shaped based on a Haar wavelet basis function. In some embodiments, the MEG waveforms include gradient waveforms corresponding to wavelet basis functions of different scales. For example, the MEG waveforms can include gradient waveforms corresponding to Haar wavelet basis functions with different scales. As another non-limiting example, the MEG waveforms include gradient waveforms that are shaped based on basis functions associated with the Fourier series. For instance, the MEG waveforms can include gradient waveforms corresponding to different harmonics of the Fourier series. More generally, the MEG waveforms can be constructed to be shaped based on one or more basis functions of a particular integral transform.

Magnetic resonance data are then acquired from a subject using an MRI system under the control of a pulse sequence that implements the MEG waveforms to generate motion encoding gradients, as indicated at step 204. When used in MRE, the magnetic resonance data are acquired while mechanical waves are propagating within the subject. For example, the mechanical waves can be generated in response to an external vibration source (e.g., a so-called MRE driver) that vibrates a portion of the subject, such that the mechanical waves are generated and propagate within the subject. Additionally or alternatively, the tissue motion can be generated in response to tissue motion intrinsic to the subject, such as cardiac and/or respiratory motion. For instance, cardiac motion can induce mechanical waves to propagate within other tissues within the subject. In still other embodiments, the tissue motion can be flow motion, such as blood flow motion. The motion encoding gradients encode the tissue motion as phase information in the magnetic resonance data. As a non-limiting example, the MRE data can include positive-phase data (e.g., data acquired with motion encoding gradients that are in-phase with the underlying vibratory motion), negative-phase data (e.g., data acquired with motion encoding gradients that are out-of-phase with the underlying vibratory motion), or both.

In some embodiments, acquiring the MRE data includes repeating the pulse sequence using different motion encoding gradients to encode different types of motion (e.g., different frequencies of motion). For example, the MEG waveforms accessed with the computer system can include a set of different MEG waveforms corresponding to different motion encoding gradients. As described above, the MEG waveforms can include waveforms based on different scales or other variations of basis functions, series, or systems. Thus, as a non-limiting example, the pulse sequence can be repeated using different motion encoding gradients that are shaped based on different scales of the wavelet basis function, series, or system. For instance, the pulse sequence can be performed using a first set of motion encoding gradients shaped based on a first scale of a wavelet basis function, series, or system, thereby acquiring first MRE data, then repeated using a second set of motion encoding gradients shaped based on a second scale of a wavelet basis function, series, or system, thereby acquiring second MRE data. Additionally or alternatively, the motion encoding gradients can be generated based on a composite gradient waveform, such as by combining a first waveform shaped based on a first scale of a wavelet basis function, series, or system, and a second waveform shaped based on a second scale of the wavelet basis function, series, or system.

Images are reconstructed from the magnetic resonance data, as indicated at step 206. In some embodiments, the images depict the tissue motion (e.g., mechanical waves propagating. blood flow) occurring in the subject when the magnetic resonance data were acquired, and whose motion were encoding by the motion encoding gradients. As such, these images may be referred to as wave images, or tissue motion images. From the wave images, the underlying tissue motion (e.g., displacement, velocity, etc.) can be estimated and/or mechanical properties of the underlying tissue can be computed or otherwise estimated, as indicated at step 208. For example, an MRE inversion algorithm or process can be implemented to compute or otherwise estimate one or more mechanical properties from the wave images. Individual mechanical property values can be estimated, or maps of mechanical properties (i.e., images that depict the spatial distribution of mechanical properties within the underlying tissues) can be generated. These individual values or maps can be displayed to a user, or stored for later use.

As described above, it is an advantage of the present disclosure that the underlying tissue motion can be decoded based on a simplified inverse transform corresponding to a group of basis functions, series, or systems on which the motion encoding gradients are based. Thus, as a non-limiting example, when the MEG waveforms are shaped based on a Haar wavelet, the underlying tissue motion can be decoded by applying an inverse Haar wavelet transform to the reconstructed wave images. Likewise, then the MEG waveforms are shaped based on a Fourier series, the underlying tissue motion can be decoded by applying an inverse Fourier transform to the reconstructed wave images. Mechanical properties can then be computed or otherwise estimated from the decoded motion data.

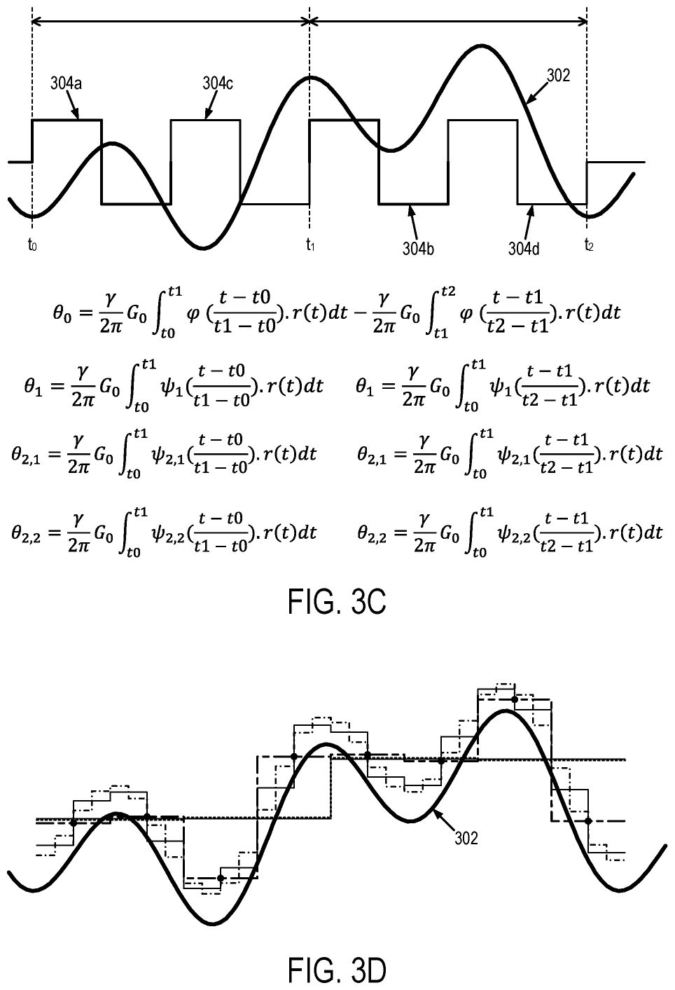

As an example, FIGS. 3A-3D illustrate the use of multiscale motion encoding gradients shaped based on different scales of a wavelet basis function (FIGS. 3A-3C), from which the underlying motion can be decoded based on an inverse wavelet transform associated with that wavelet basis (FIG. 3D). For example, FIG. 3A illustrates the use of a motion encoding gradient shaped based on an MEG waveform 304 that is based on a Haar wavelet. The motion encoding gradient is used to encode a multifrequency motion profile 302, and results in the phase, θ₀, of being encoded in the MRE data. FIG. 3B illustrates the use of motion encoding gradients based on MEG waveforms 304a, 304b that are shaped on different scales of the Haar wavelet, and which encode the phases θ₁ in the MRE data. FIG. 3C illustrates the use of motion encoding gradients based on MEG waveforms 304a, 304b, 304c, 304d that are shaped on different scales of the Haar wavelet, and which encode the phases θ_{2,1} (MEG waveforms 304a, 304b) and θ_{2,2} (MEG waveforms 304c, 304d) in the MRE data. The underlying motion profile 302 can then be decoded based on an inverse Haar wavelet transform. For example, the phases can be decoded based on the following:

$${f}_{0} ( t ) = - \frac{2 π}{γ {G}_{0} {2}^{n}} {θ}_{0} φ ( t )$$

$${f}_{1} ( t ) = \frac{2 π}{γ {G}_{0} {2}^{n}} ( {θ}_{0} φ ( t ) + {θ}_{1} ψ ( t ) )$$

$${f}_{n} ( t ) = \frac{2 π}{γ {G}_{0} {2}^{n}} ( {θ}_{0} φ ( t ) + {θ}_{1} ψ ( t ) + {\sum }_{\begin{matrix}2 \leq j \leq n \\ 0 \leq k < {2}^{j - 1}\end{matrix}} {θ}_{j , k} {ψ}_{j , k} ( t ) )$$

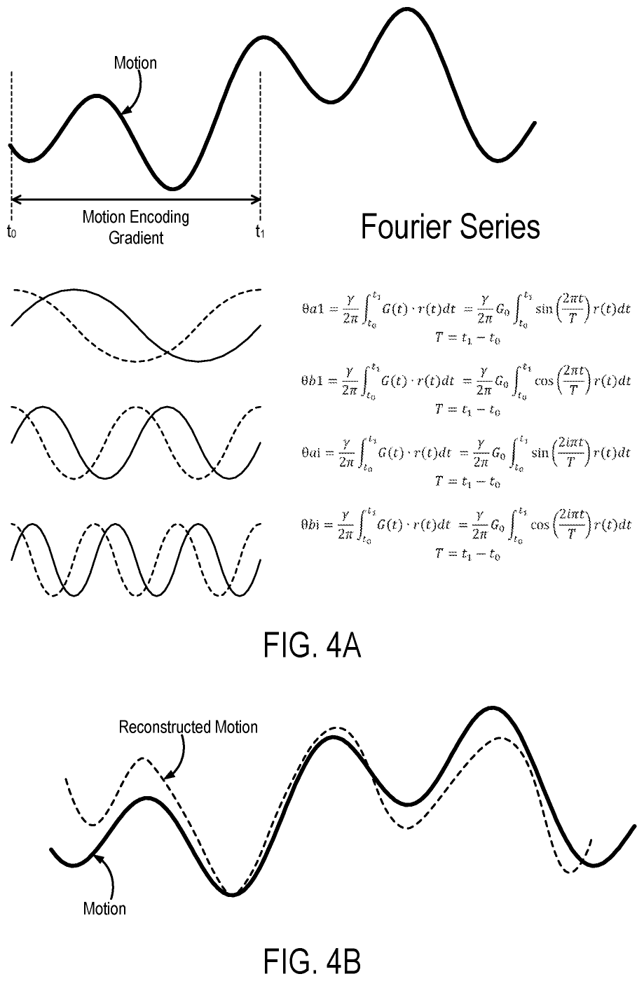

As another example, FIG. 4A illustrates the use of multiscale motion encoding gradients shaped based on different harmonics of a Fourier series, from which the underlying motion can be decoded based on an inverse Fourier transform associated with that wavelet basis, as illustrated in FIG. 4B.

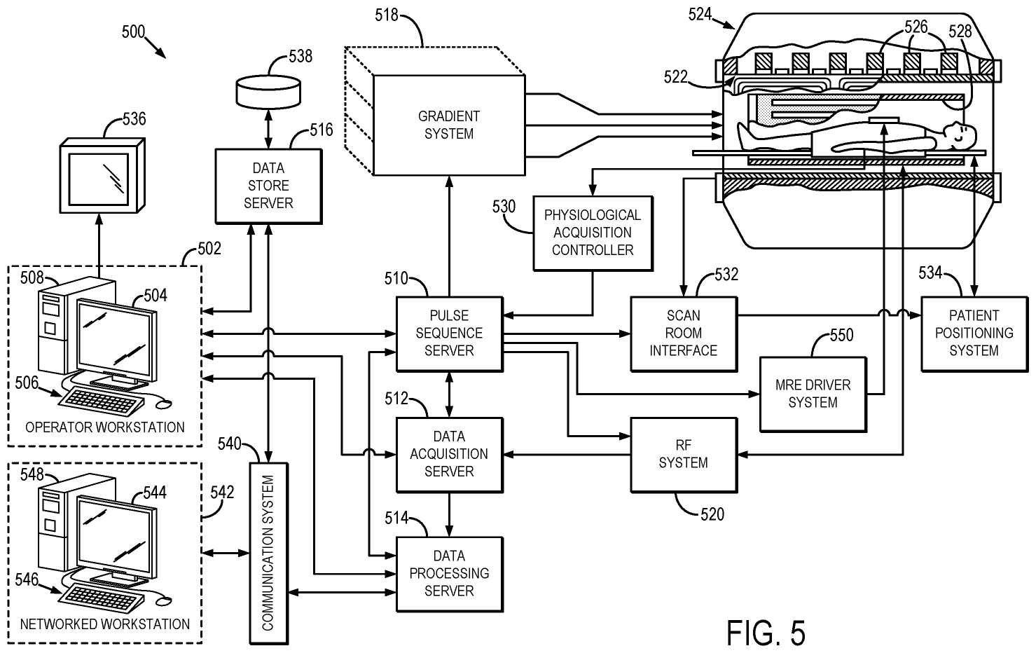

Referring particularly now to FIG. 5, an example of a magnetic resonance imaging (“MRI”) system 500 that can implement the methods described here is illustrated. The MRI system 500 includes an operator workstation 502 that may include a display 504, one or more input devices 506 (e.g., a keyboard, a mouse), and a processor 508. The processor 508 may include a commercially available programmable machine running a commercially available operating system. The operator workstation 502 provides an operator interface that facilitates entering scan parameters into the MRI system 500. The operator workstation 502 may be coupled to different servers, including, for example, a pulse sequence server 510, a data acquisition server 512, a data processing server 514, and a data store server 516. The operator workstation 502 and the servers 510, 512, 514, and 516 may be connected via a communication system 540, which may include wired or wireless network connections.

The pulse sequence server 510 functions in response to instructions provided by the operator workstation 502 to operate a gradient system 518 and a radiofrequency (“RF”) system 520. Gradient waveforms for performing a prescribed scan are produced and applied to the gradient system 518, which then excites gradient coils in an assembly 522 to produce the magnetic field gradients Gₓ, G_{y}, and G_{z} that are used for spatially encoding magnetic resonance signals. The gradient coil assembly 522 forms part of a magnet assembly 524 that includes a polarizing magnet 526 and a whole-body RF coil 528.

RF waveforms are applied by the RF system 520 to the RF coil 528, or a separate local coil to perform the prescribed magnetic resonance pulse sequence. Responsive magnetic resonance signals detected by the RF coil 528, or a separate local coil, are received by the RF system 520. The responsive magnetic resonance signals may be amplified, demodulated, filtered, and digitized under direction of commands produced by the pulse sequence server 510. The RF system 520 includes an RF transmitter for producing a wide variety of RF pulses used in MRI pulse sequences. The RF transmitter is responsive to the prescribed scan and direction from the pulse sequence server 510 to produce RF pulses of the desired frequency, phase, and pulse amplitude waveform. The generated RF pulses may be applied to the whole-body RF coil 528 or to one or more local coils or coil arrays.

The RF system 520 also includes one or more RF receiver channels. An RF receiver channel includes an RF preamplifier that amplifies the magnetic resonance signal received by the coil 528 to which it is connected, and a detector that detects and digitizes the I and Q quadrature components of the received magnetic resonance signal. The magnitude of the received magnetic resonance signal may, therefore, be determined at a sampled point by the square root of the sum of the squares of the I and Q components:

$$M = \sqrt{{I}^{2} + {Q}^{2}} ; \qquad ( 1 )$$

and the phase of the received magnetic resonance signal may also be determined according to the following relationship:

$$φ = {tan}^{- 1} ( \frac{Q}{I} ) . \qquad ( 2 )$$

The pulse sequence server 510 may receive patient data from a physiological acquisition controller 530. By way of example, the physiological acquisition controller 530 may receive signals from a number of different sensors connected to the patient, including electrocardiogramh (“ECG”) signals from electrodes, or respiratory signals from a respiratory bellows or other respiratory monitoring devices. These signals may be used by the pulse sequence server 510 to synchronize, or “gate,” the performance of the scan with the subject's heart beat or respiration.

The pulse sequence server 510 may also connect to a scan room interface circuit 532 that receives signals from various sensors associated with the condition of the patient and the magnet system. Through the scan room interface circuit 532, a patient positioning system 534 can receive commands to move the patient to desired positions during the scan.

The pulse sequence server 510 may also connect to an MRE driver system 550 that can be used to impart a vibration or other mechanical force to a subject in order induce mechanical waves or other vibratory motion within one or more tissues of the subject. For example, the MRE driver system 550 can include one or more of an active driver and/or a passive driver for creating vibratory motion or other mechanical forces. The drivers can be controlled by control hardware and/or logic as part of the MRE driver system 550. For example, the MRE driver system 550 can be configured to generate multifrequency or other composite vibratory motion, such that multifrequency mechanical waves propagate in the subject. The pulse sequence server 510 can construct motion encoding gradient waveforms and otherwise such waveforms to the gradient system 518 to generate motion encoding gradients that are shaped based on one or more wavelet basis functions, series, or systems, as described in the present disclosure.

The digitized magnetic resonance signal samples produced by the RF system 520 are received by the data acquisition server 512. The data acquisition server 512 operates in response to instructions downloaded from the operator workstation 502 to receive the real-time magnetic resonance data and provide buffer storage, so that data is not lost by data overrun. In some scans, the data acquisition server 512 passes the acquired magnetic resonance data to the data processor server 514. In scans that require information derived from acquired magnetic resonance data to control the further performance of the scan, the data acquisition server 512 may be programmed to produce such information and convey it to the pulse sequence server 510. For example, during pre-scans, magnetic resonance data may be acquired and used to calibrate the pulse sequence performed by the pulse sequence server 510. As another example, navigator signals may be acquired and used to adjust the operating parameters of the RF system 520 or the gradient system 518, or to control the view order in which k-space is sampled. In still another example, the data acquisition server 512 may also process magnetic resonance signals used to detect the arrival of a contrast agent in a magnetic resonance angiography (“MRA”) scan. For example, the data acquisition server 512 may acquire magnetic resonance data and processes it in real-time to produce information that is used to control the scan.

The data processing server 514 receives magnetic resonance data from the data acquisition server 512 and processes the magnetic resonance data in accordance with instructions provided by the operator workstation 502. Such processing may include, for example, reconstructing two-dimensional or three-dimensional images by performing a Fourier transformation of raw k-space data, performing other image reconstruction algorithms (e.g., iterative or backprojection reconstruction algorithms), applying filters to raw k-space data or to reconstructed images, generating functional magnetic resonance images, or calculating motion or flow images.

Images reconstructed by the data processing server 514 are conveyed back to the operator workstation 502 for storage. Real-time images may be stored in a data base memory cache, from which they may be output to operator display 502 or a display 536. Batch mode images or selected real time images may be stored in a host database on disc storage 538. When such images have been reconstructed and transferred to storage, the data processing server 514 may notify the data store server 516 on the operator workstation 502. The operator workstation 502 may be used by an operator to archive the images, produce films, or send the images via a network to other facilities.

The MRI system 500 may also include one or more networked workstations 542. For example, a networked workstation 542 may include a display 544, one or more input devices 546 (e.g., a keyboard, a mouse), and a processor 548. The networked workstation 542 may be located within the same facility as the operator workstation 502, or in a different facility, such as a different healthcare institution or clinic.

The networked workstation 542 may gain remote access to the data processing server 514 or data store server 516 via the communication system 540. Accordingly, multiple networked workstations 542 may have access to the data processing server 514 and the data store server 516. In this manner, magnetic resonance data, reconstructed images, or other data may be exchanged between the data processing server 514 or the data store server 516 and the networked workstations 542, such that the data or images may be remotely processed by a networked workstation 542.

The present disclosure has described one or more preferred embodiments, and it should be appreciated that many equivalents, alternatives, variations, and modifications, aside from those expressly stated, are possible and within the scope of the invention.

1. A method for magnetic resonance imaging, the method comprising:
(a) acquiring magnetic resonance data from a subject using a magnetic resonance imaging system while tissue motion is occurring in at least one tissue of the subject, the MRI system performing a pulse sequence that includes motion encoding gradients that are shaped based on a basis function of an integral transform;
(b) reconstructing images from the magnetic resonance data; and
(c) generating motion data from the images by applying an inverse transform to the images, wherein the inverse transform is an inverse of the integral transform associated with the basis function.

2. The method of claim 1, wherein the basis function is a wavelet basis function.

3. The method of claim 2, wherein the wavelet basis function is a Haar wavelet basis function.

4. The method of claim 3, wherein the inverse transform is an inverse Haar wavelet transform.

5. The method of claim 1, wherein the basis function is a Fourier series basis function.

6. The method of claim 1, wherein the motion encoding gradients are shaped based on a plurality of different scales of the basis function.

7. The method of claim 6, wherein the basis function is a Haar wavelet basis function and the motion encoding gradients are shaped based on different scales of the Haar wavelet basis function.

8. The method of claim 6, wherein the basis function is a Fourier series basis function and the motion encoding gradients are shaped based on different harmonics of a Fourier series.

9. The method of claim 6, wherein the motion encoding gradients comprise a composite motion encoding gradient based on a composite of gradient waveforms shaped based on the plurality of different scales of the basis function.

10. The method of claim 6, wherein the plurality of different scales correspond to a scaling function that scales the basis function with different scaling factors as a function of time.

11. The method of claim 1, further comprising estimating mechanical property value data from the motion data, wherein the mechanical property value data are indicative of a mechanical property of the at least one tissue in the subject.

12. The method of claim 11, wherein the mechanical property value data comprise a mechanical property map that depicts a spatial distribution of mechanical property values within the subject.

13. The method of claim 1, wherein the motion data comprise estimates of at least one of displacement or velocity associated with the tissue motion.

14. A magnetic resonance imaging (MRI) system, comprising:
a main magnet configured to generate a polarizing magnetic field;
a gradient system comprising at least one gradient coil configured to generate a magnetic field gradient;
a radio frequency (RF) system comprising at least one RF coil;
a computer system in communication with the gradient system and the RF system and configured to:
access a motion encoding gradient waveform that is shaped based on a basis function of an integral transform; and
control the gradient system to generate the magnetic field gradient in response to the motion encoding gradient waveform.

15. The MRI system of claim 14, wherein the computer system is configured to access the motion encoding gradient waveform by retrieving the motion encoding gradient waveform from a memory of the computer system.

16. The MRI system of claim 14, wherein the motion encoding gradient waveform is shaped based on a wavelet basis function.

17. The MRI system of claim 16, wherein the wavelet basis function is a Haar wavelet basis function.

18. The MRI system of claim 14, wherein the motion encoding gradient waveform is shaped based on a Fourier series basis function.

19. The MRI system of claim 14, wherein the motion encoding gradient waveform is shaped based on a multiscale basis function comprising basis functions corresponding to a base function that is scaled by different scaling factors.

20. The MRI system of claim 19, wherein the computer system is configured to control the gradient system to generate the magnetic field gradient based on a composite of the multiscale basis function.
